(19) United States
(12) Patent Application Publication
(10) Pub. No.: US 2024/0395913 A1
(43) Pub. Date: Nov. 28, 2024

(54) SEMICONDUCTOR SWITCHING DEVICES, COMPOSITE SUBSTRATES THEREFOR, AND METHODS OF USE

(71) Applicant: The Trustees of Indiana University, Bloomington, IN (US)

(72) Inventors: Haitham Kanakri, Indianapolis, IN (US); Maher Rizkalla, Carmel, IN (US); Euzeli Cipriano Dos Santos, JR., Zionsville, IN (US)

(21) Appl. No.: 18/663,795

(22) Filed: May 14, 2024

Related U.S. Application Data
(60) Provisional application No. 63/503,534, filed on May 22, 2023.

(51) Int. Cl. H01L 29/739; H01L 23/495; H01L 29/16; H01L 29/66

(52) U.S. Cl. CPC H01L 29/7394; H01L 23/49568; H01L 29/1606; H01L 29/66325; H01L 29/6678

(57) ABSTRACT

Composite substrates for use in semiconductor switching devices, including insulated gate bipolar transistors (IGBT), switching devices formed therewith, and methods of use. The composite substrate includes a nano-scale graphene film on a sapphire-containing surface of a dielectric substrate, wherein the nano-scale graphene film and sapphire-containing surface exhibit lattice alignment properties capable of improving thermal performance of the switching device and reducing local temperature hotspots in the switching device.

### CROSS-REFERENCE TO RELATED APPLICATIONS

This application claims the benefit of provisional U.S. Patent Application No. 63/503,534 filed May 22, 2023, the contents of which are incorporated herein by reference.

### BACKGROUND OF THE INVENTION

The invention generally relates to semiconductors and devices formed therewith. The invention specifically relates to composite substrates capable of use in semiconductor switching devices, including but not limited to insulated gate bipolar transistors (IGBT), switching devices formed therewith, and methods of use.

Demand for extremely efficient power converters has grown in a variety of industries including aerospace, defense, and electric vehicles. Consequently, this has increased the demand for highly efficient switching devices within those converters, especially semiconductor switching devices that are designed to process high amounts of power. Currently, a variety of high-power switching devices have been developed and explored, including metal oxide semiconductor (MOSFET) switches and gallium nitride (GaN) devices. Insulated gate bipolar transistors (IGBTs) are one such category of semiconductor devices that have found advantageous application in the aforementioned power switching devices.

An IGBT switching device is a three-terminal power switch that can be designed to provide fast switching at high efficiency, the three terminals being a gate, an emitter, and a collector. The conduction terminals are the collector and emitter, and the gate functions as a control terminal. As an example of existing IGBT switching devices, an IGBT semiconductor chip and a diode semiconductor chip are bonded to a conductive (e.g., copper) track layer (also called a trace layer). The track layer can include one or more individual tracks (traces). Bond wires electrically connect the chips to the track layer. The track layer is soldered to a substrate formed of a dielectric material, and the substrate is soldered to a base plate on a side of the substrate opposite the chips. The heat sink is typically bonded to the base plate on a side of the base plate opposite the substrate. The emitter and gate terminals are connected to the track layer. In this manner, heat generated by the chips is conducted through the track layer, substrate, and base plate to the heat sink, and then dissipated to the surrounding environment.

Typically, heat generated by switching and conduction losses is the main source of failure in these switches, as it generates bond wire defects due to the heating and cooling of the wires during normal operation and can result in the bond wires fracturing or detaching from the track layer. This may favor materials with higher thermal conductivities or effective composite substrate designs in order to reduce the likelihood or onset of such failures. Consequently, high power switching devices such as IGBTs often require significant heat dissipation capabilities, specifically heat spreaders or heat sinks that dissipate the heat generated by switching and conduction losses. Heat sinks for such purposes are designed to have a volume that is roughly proportional to the amount of power being processed. The minimum size of a heat sink is determined by the amount of power being processed which in turn increases the overall size of a component in which the switching device is used, for example, a power converter. Applications for switching devices may not accept bulky heat sinks, especially as the scale of design in many applications and the components therein continues to become smaller. Furthermore, failures in switches in such applications continue to become less tolerable, as the performance demands increase, and the smaller scale of construction makes repair difficult or completely infeasible.

In an effort to increase the thermal resilience of such devices, new materials in various elements of the IGBTs have been explored. In particular, graphene is one such material that exhibits advantageous thermal characteristics, including a high thermal conductivity of about 5000 W/mK at room temperature. Graphene also exhibits a high breaking strength of about 40 N/m. Graphene has demonstrated exceptional abilities in its application as a thin film inside the structure of IGBT devices. However, due to its application at the micro- and nano-scale, applying graphene presents challenges. For example, the performance of graphene grown on a substrate in IGBTs is highly dependent on the strength of its chemical bond between the graphene and components attached thereto. Existing IGBT devices typically use aluminum oxide or a composite thereof as a substrate. Of particular note, the alignment between the lattices of a thin graphene film and the substrate to which it is applied is critical. Substrates with mismatched lattices may cause poor thermal efficiency and result in the aforementioned failures due to thermal mismatching between layers, generating concentrations of thermal energy which lead to failures of the types noted above.

In light of the aforementioned challenges associated with emerging switching device applications, and the low tolerance for individual component failure, it would be advantageous if switching devices were better capable of harnessing thermal advantages associated with graphene while mitigating its known challenges.

### BRIEF SUMMARY OF THE INVENTION

The intent of this section of the specification is to briefly indicate the nature and substance of the invention, as opposed to an exhaustive statement of all subject matter and aspects of the invention. Therefore, while this section identifies subject matter recited in the claims, additional subject matter and aspects relating to the invention are set forth in other sections of the specification, particularly the detailed description, as well as any drawings.

The present invention provides, but is not limited to, composite substrates capable of use in semiconductor switching devices, including but not limited to insulated gate bipolar transistors (IGBT), switching devices equipped with such composite substrates, and methods of use.

According to nonlimiting aspects of the invention, a composite substrate is provided for use in IGBT switching devices. The composite substrate includes a dielectric substrate having at least a first surface formed of sapphire, and a nano-scale graphene film on the first surface of the dielectric substrate.

According to another nonlimiting aspect of the invention, an IGBT switching device is provided that is suitable for high power, high switching frequency applications. The IGBT switching device includes a composite substrate formed of a dielectric substrate having at least a first surface formed of sapphire and a nano-scale graphene film on the first surface of the dielectric substrate, a conductor layer bonded to a second surface of the composite substrate, at least one IGBT chip and at least one diode chip electrically connected to the conductor layer with bond wires, and a base plate bonded to the nano-scale graphene layer of the composite substrate. The IGBT switching device may optionally include a heat sink.

According to a second nonlimiting aspect of the invention, a method is provided for improving the thermal performance of an IGBT switching device that comprises a dielectric substrate and a nano-scale graphene film. The method comprises reducing a lattice mismatch between a surface of the dielectric substrate and the nano-scale graphene film.

Technical aspects of composite substrates, switching devices, and methods having features as described above preferably include the ability to utilize advantages associated with graphene while overcoming thermal inefficiency associated with mismatched lattices. IGBT switching devices as described above have been shown through finite element analysis (FEA) modeling to be capable of exhibiting improved thermal impedance over aluminum oxide-based substrates. Due to improved electrical, thermal, and mechanical properties, sapphire-based substrates mitigate lattice mismatch with graphene layers and ensuing issues and are therefore potentially advantageous in high power switching applications.

These and other aspects, arrangements, features, and/or technical effects will become apparent upon detailed inspection of the figures and the following description.

### BRIEF DESCRIPTION OF THE DRAWINGS

FIGS. 1A and 1B schematically represent cross-sectional views of IGBT switching devices in accordance with nonlimiting embodiments of the invention.

FIGS. 2 and 3 schematically represent three-dimensional models of IGBT switching devices that were analyzed by finite element analysis (FEA).

FIG. 4A is a 2-dimensional plan view of a portion of the IGBT switching devices of FIGS. 2 and 3.

FIG. 4B correlates the three-dimensional model of the IGBT switching device in FIG. 2 and a half-bridge inverter circuit diagram.

FIG. 4C is a schematic representation of a simplified capacitance matrix of the IGBT switching device.

### DETAILED DESCRIPTION OF THE INVENTION

The intended purpose of the following detailed description of the invention and the phraseology and terminology employed therein is to describe what is shown in the drawings, which depict and/or relate to one or more nonlimiting embodiments of the invention, and to describe certain but not all aspects of the embodiment(s) depicted in the drawings. The following detailed description also identifies certain but not all alternatives of the embodiment(s) depicted in the drawings. As nonlimiting examples, the invention encompasses additional or alternative embodiments in which one or more features or aspects shown and/or described as part of a particular embodiment could be eliminated, and also encompasses additional or alternative embodiments that combine two or more features or aspects shown and/or described as part of different embodiments. Therefore, the appended claims, and not the detailed description, are intended to particularly point out subject matter regarded to be aspects of the invention, including certain but not necessarily all of the aspects and alternatives described in the detailed description.

To facilitate the description provided below of the embodiment(s) represented in the drawings, relative terms, including but not limited to, “proximal,” “distal,” “anterior,” “posterior,” “vertical,” “horizontal,” “lateral,” “front,” “rear,” “side,” “forward,” “rearward,” “top,” “bottom,” “upper,” “lower,” “above,” “below,” “right,” “left,” etc., may be used in reference to composite substrates, IGBT switching devices, and components as represented in the drawings. All such relative terms are useful to describe the illustrated embodiment(s) but should not be otherwise interpreted as limiting the scope of the invention.

As used herein the terms “a” and “an” to introduce a feature are used as open-ended, inclusive terms to refer to at least one, or one or more of the features, and are not limited to only one such feature unless otherwise expressly indicated. Similarly, use of the term “the” in reference to a feature previously introduced using the term “a” or “an” does not thereafter limit the feature to only a single instance of such feature unless otherwise expressly indicated.

In some nonlimiting aspects of the invention, a composite substrate is provided that is capable of use in semiconductor switching device applications, including IGBT switching devices. The composite substrate may include a nano-scale graphene film on and contacting a surface of a dielectric substrate. At least the surface of the dielectric substrate contacted by the nano-scale graphene film is formed of sapphire. As used herein, the term “nano-scale” denotes thicknesses of less than one micrometer in the nanometer range, such as about 0.1 nm to about 999 nm, and in some preferred cases thicknesses of less than 500 nanometers. In some configurations, the composite substrate may exhibit improved thermal performance characteristics resulting from a reduced lattice mismatch between the graphene film and sapphire substrate as compared to the lattice mismatch between graphene films and substrates commonly formed of aluminum oxide (alumina, Al₂O₃). The nano-scale graphene film is capable of improving the overall thermal performance of a switching device by more effectively transferring heat therethrough that is generated by switching and conduction occurring within the switching device and is desired to be conducted to a heat sink or other structure. The composite substrate is particularly well suited for use in switching devices that require a high power density and/or a high switching frequency, as nonlimiting examples, power converters used in aerospace, defense, and electric vehicle applications.

Without being bound by theory, it is believed that the composite substrate is capable of exhibiting improved thermal performance due to the interplay between the nano-scale graphene film and sapphire in/of the substrate on which it is deposited. Recognized limiting factors in the use of graphene films include challenges associated with their physical application to devices or surfaces at small scales. In existing IGBT technologies in which IGBT semiconductor devices are supported on substrates often formed of aluminum oxide, lattice mismatch occurs between the substrate and graphene deposited thereon. Such lattice mismatch results in inefficiencies in thermal transfer that may promote an overall reduction in the thermal performance of the IGBT device, thereby requiring greater heat sink volume and constraining the intended advantages provided by the addition of a graphene film. Furthermore, these inefficiencies may generate local hotspots, possibly resulting in detachment or component failure at those locations, further exacerbating underlying thermal management issues and resulting in overall device failure or performance degradation.

As used herein, sapphire refers to the mineral corundum, preferably consisting entirely or essentially of alpha-alumina (α-Al₂O₃) characterized by a rhombohedral crystal structure and containing little or no gamma (γ), delta (δ) and theta (θ) alumina. Sapphire is advantageous over other aluminum oxide materials in terms of their electrical, thermal, and mechanical properties. By providing a substrate having at least a surface formed of and optionally consisting of sapphire, the aforementioned lattice mismatch constraints are largely mitigated due to the high durability and purity of the sapphire substrate. This results in a significant improvement in the thermal conductivity at the graphene-substrate interface and the substrate itself, thereby improving the overall thermal response of the device and reducing the required heat sink volume. Furthermore, improved thermal conductivity reduces the likelihood of failure or degradation at the nano- and micro-level, likewise improving the thermal robustness of the IGBT device in which it is provided.

In view of the above, another aspect of the invention is the capability of providing an IGBT switching device that is suitable for high power, high switching frequency applications. Such an IGBT switching device comprises at least one IGBT chip and at least one diode chip, each bonded to an electrically-conductive track layer by bond wires. At least one gate terminal and at least one emitter terminal are connected to the conductor layer, which is bonded to the composite substrate.

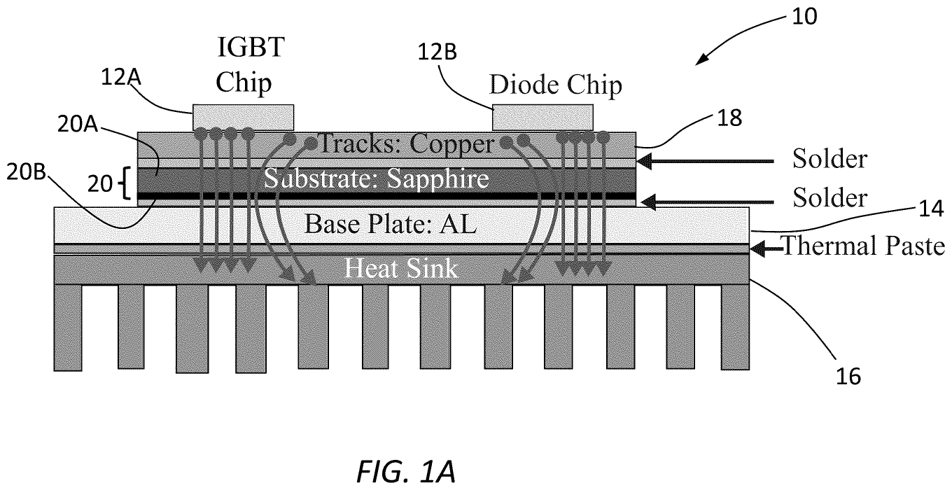

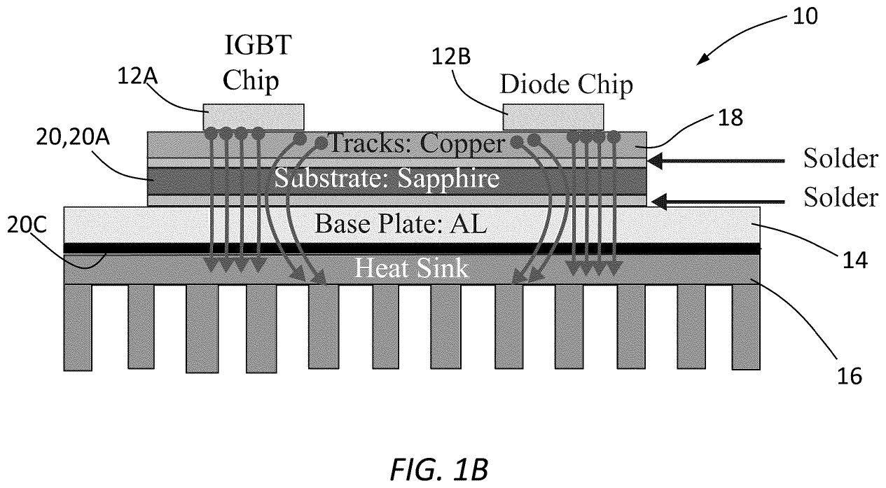

FIG. 1A schematically represents a cross-sectional view of an IGBT switching device 10 and exemplary heat conduction paths from semiconductor chips 12A and 12B located at an upper surface of the switching device 10 to a base plate 14 and heat sink 16 located at a lower surface of the device 10. The semiconductor chips 12A and 12B are identified in FIG. 1A as an IGBT chip 12A and a diode chip 12B, each bonded to a copper track layer 18 that in turn is bonded to a composite substrate 20, for example with a layer of solder. The composite substrate 20 is represented as comprising a sapphire substrate 20A having an upper surface to which the track layer 18 is soldered, and a nano-scale graphene film (layer) 20B disposed at an oppositely-disposed lower surface of the sapphire substrate 20A. FIG. 1A further represents the base plate 14 as bonded to the nano-scale graphene film 20B, for example, with a layer of solder. FIG. 1B represents another embodiment of an IGBT switching device 10 in which a nano-scale graphene film (layer) 20C is present and sandwiched between the base plate 14 and the heat sink 16. The nano-scale graphene film 20C may be in addition or in place of the nano-scale graphene film 20B of FIG. 1A.

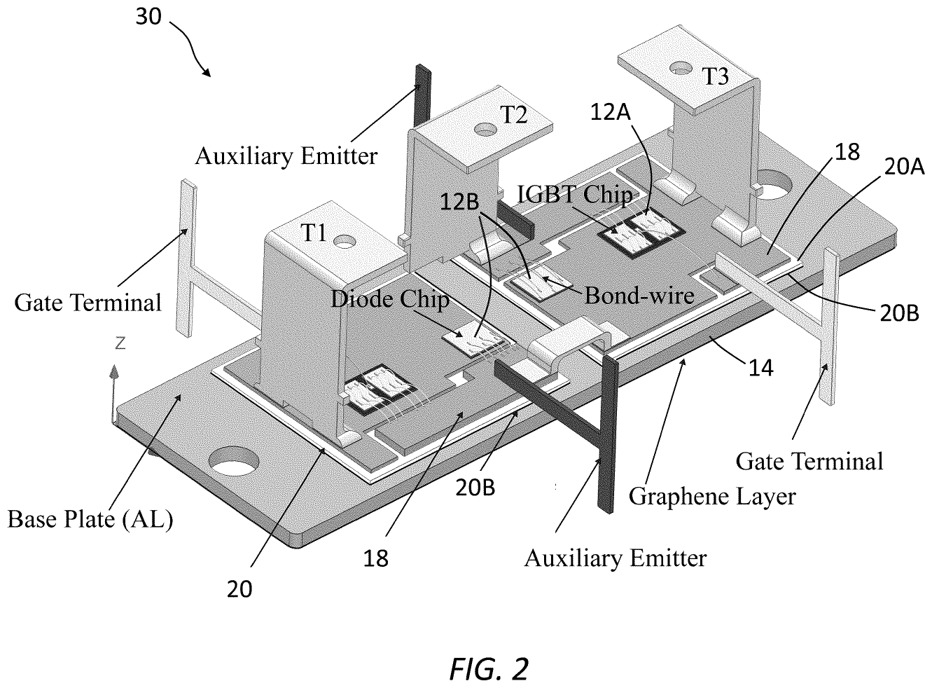

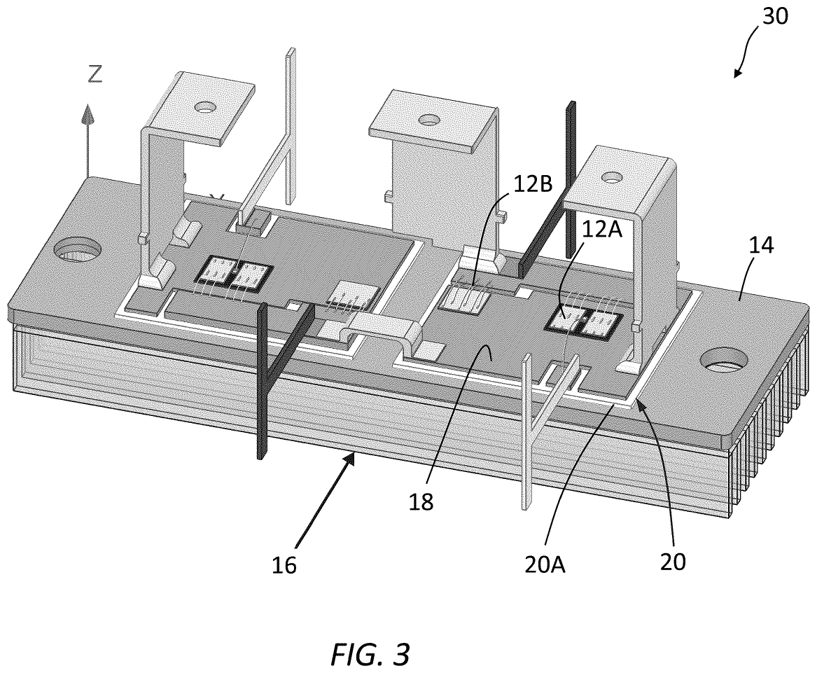

FIGS. 2 and 3 represent 3-D models of an IGBT switching device 30 similar to the switching devices 10 represented in FIGS. 1A and 1B. In particular, the switching device 30 is representative of an Infineon BSM75GB60DLC half-bridge based IGBT inverter, whose dimensions include a length of 94 mm and a width of 34 mm. The model includes two 5 mm×3 mm IGBT chips 12A and two 5 mm×5 mm power diodes 12B. The electrical connections are modeled as bond wires and traces. The bond wires are modeled as aluminum and the trace layer 18 is modeled as copper.

The bond wires are often the location of local hotspots due to thermal transfer inefficiencies and are potentially a source of component degradation or failure, necessitating efficient thermal transfer from the chips. For purposes of testing and employment, the maximum thermal operating limits of IGBT components, specifically local hotspots, was determined to be 150° C., and the maximum operation temperature of the IGBT itself was determined to be 125° C. per the Infineon BSM75GB60DLC device datasheet.

The semiconductor IGBT chips 12A and diode chips 12B were modeled as soldered to a dielectric substrate 20 that provides electrical insulation and thermal transfer to a base plate 14. In some investigations, the substrate 20 was modeled as entirely composed of a sapphire substrate 20A having a thickness of 0.5 millimeter (mm). The base plate 14 was modeled as entirely composed of aluminum, which transfers heat to a heat sink 16 (e.g., as illustrated in FIG. 3). In such an IGBT device, thermal energy must be conducted through the various different material layers, and therefore the heat conduction path is dependent on the thickness and composition of each layer. Thermal conductivity is an intrinsic property of each material, and it is determined by the transport of electrons and phonons. In 2-D materials such as graphene nano-layers, thermal conductivity is determined primarily by the transfer of phonons, as free electrons are limited in such a geometry. Moreover, heat conduction in the material is governed by Fourier's law describing the movement of heat in material due to the collision of molecular and atomic particles. This law is provided in the equation

$$q = - k \overline{V} T ,$$

where q is the local heat flux, measured in Watts per square meters, k is the thermal conductivity of the material, and ∇T is the local temperature gradient. By introducing a nano-scale graphene film (e.g., 20B in FIG. 2) in combination with a sapphire substrate 20A as elements of the substrate 20, the heat conduction path through the various layers described above was analytically shown to gain overall efficiency compared to traditional aluminum oxide substrate without a graphene layer.

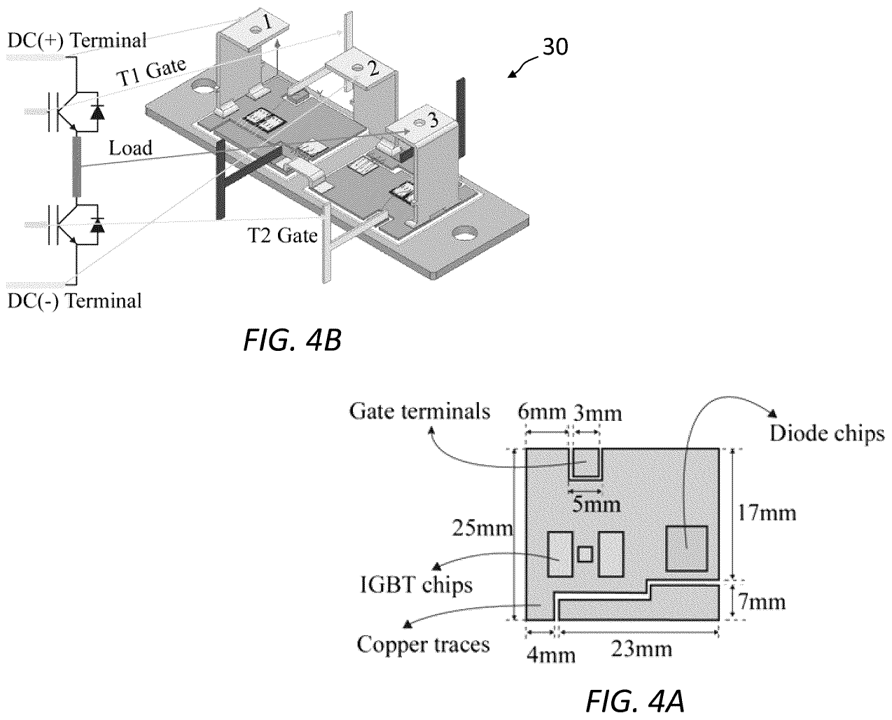

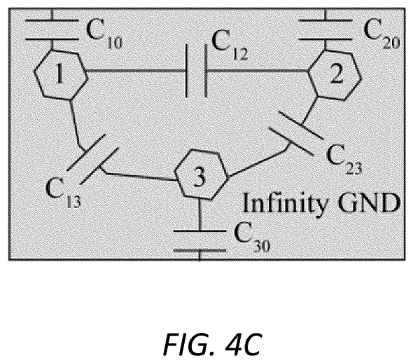

FIG. 4A provides details and dimensions of part of the IGBT switching device 30. FIG. 4B illustrates the correlation between the IGBT switching device 30 and a single-phase half bridge inverter circuit. FIG. 4C illustrates an electrical schematic representing the capacitance matrix. The capacitance C is calculated based on a total charge Q in a capacitor with a potential difference V, as related in the equation Q=CV. The off diagonal of this matrix is always negative in order to account for the sign of charge on each conductor. The values of the matrix are linked to the finite element analysis solver for electro-thermal analysis as known in the art. The results of the finite element analysis are used below to ascertain the properties of variations of the 3-D models of IGBT switching devices of FIGS. 2 and 3.

The analysis assessed graphene films (e.g., 20B and/or 20C) having different thicknesses of 10 nm, 200 nm, and 500 nm. Comparisons were made of the simulated thermal performances of the IGBT switching device models with nano-scale graphene films of varying thickness provided in the composite substrate, with and without the inclusion of a heat sink. As known, heat sinks are often required in existing IGBT switching devices in order to effectively dissipate thermal energy. Heat sinks can be generally described as a three-dimensional component having a base and fins that extend from the base to radiate thermal energy into an ambient environment. Extruded heat sinks, crosscut extrusion heat sinks, and cylindrical pin heat sinks are various types of heat sinks that have been explored and are known to those skilled in the art. For the purposes of the finite element analysis, an extruded heat sink was modeled. Investigations were conducted relative to the temperature distribution of an IGBT switching devices with and without a nano-scale graphene film (e.g., 20B and/or 20C), the temperature distribution of an IGBT switching device with a nano-scale graphene film of thickness 10 nanometers (nm), the temperature distribution of an IGBT switching device with a nano-scale graphene film of thickness 20 nm, the maximum temperature distribution of IGBT switching devices with different nano-scale graphene film thicknesses. The IGBT switching devices demonstrated comparable heat distribution and thermal performance characteristics and the reduced heat sink volume of the IGBT switching device equipped with a nano-scale graphene film. In a conventional IGBT switching device without a nano-scale graphene film, the maximum temperature was observed to be 169.5° C., requiring the heat sink to dissipate at least 20° C. in order to operate the IGBT switching device within industry and experimental standards. This necessitated a heat sink volume of 54 cubic centimeters. In models employing a 10 nm-thick nano-scale graphene film, the temperature in the local hot spots was reduced by 17.86° C. relative to an IGBT switching device without a graphene nanolayer. This temperature reduction relates to a 10.54% reduction in required heat sink volume, conferring significant advantages in the application of associated IGBT switching devices. Based solely on the overall device operating temperature with a constraint of 125° C., the 200 nm-thick nano-scale graphene film reduced the heat sink volume requirement to 27 cubic centimeters, relating to a 50% decrease in heat sink volume. In models employing a 200 nm-thick nano-scale graphene film, the thicker nano-scale graphene film lowered the local hotspot temperature by 48.23° C. when operated at a 75A load current, indicating a thermal reduction of 28.45% at the hotspots. Furthermore, this brought the IGBT switching device within safe operating temperature limits, as defined by industry standards, below 125° C. without necessitating a heat sink. This confers significant advantages for IGBT switching devices in applications with significant volume constraints. No significant change in thermal performance was observed in models employing a 500 nm-thick nano-scale graphene film as compared to models using a 200 nm-thick graphene film. As such, a nano-scale graphene film having a thickness of about 200 nm was concluded to be very suitable for the particular type of IGBT switching devices that were modeled, though greater thicknesses are foreseeable for switching devices configured differently than the tested models. Nano-scale graphene film thicknesses of about 10 nm to about 200 nm are believed to be suitable IGBT switching devices that were modeled, with particularly suitable thicknesses believed to depend on the volume requirements of an IGBT switching device and on its application. Within this thickness range, the thermal response of the modeled switching device was shown to be greatly improved, leading to higher system efficiency, reduction in size requirements, and reduced temperatures and local hotspots that decrease the likelihood of degradation or failure in both the switching device and its individual components. As a result, the lifetime of an IGBT switching device may be extended, which furthermore increases its utility in applications wherein replacement or repair of such devices is significantly disadvantageous or even completely infeasible.

In view of the above investigations, it is believed that an additional aspect of the invention is a method capable of increasing the thermal response and efficiency of an IGBT switching device by reducing a lattice mismatch between with a surface of a dielectric substrate of the device and a nano-scale graphene film applied to a surface of the substrate.

As previously noted above, though the foregoing detailed description describes certain aspects of one or more particular embodiments of the invention, alternatives could be adopted by one skilled in the art. For example, the IGBT and its components could differ in appearance, dimension, and construction from the embodiments described herein and shown in the drawings, functions of certain components of the IGBT could be performed by components of different construction but capable of a similar (though not necessarily equivalent) function, and various materials could be used in the fabrication of the IGBT and/or its components. As such, and again as was previously noted, it should be understood that the invention is not necessarily limited to any particular embodiment described herein or illustrated in the drawings.

1. A composite substrate for use in a switching device, the composite substrate comprising:
a dielectric substrate having at least a first surface formed of sapphire; and
a nano-scale graphene film on the first surface of the dielectric substrate.

2. The composite substrate of claim 1, wherein the nano-scale graphene film has less lattice mismatch with the first surface of the dielectric substrate than if the first surface was formed by an aluminum oxide material that contains phases other than α-Al₂O₃.

3. The composite substrate of claim 1, wherein the nano-scale graphene film has a thickness of less than one micrometer.

4. The composite substrate of claim 3, wherein the nano-scale graphene film has a thickness of 500 nanometers or less.

5. The composite substrate of claim 4, wherein the nano-scale graphene film has a thickness of 200 nanometers or less.

6. The composite substrate of claim 5, wherein the nano-scale graphene film has a thickness of about 200 nanometers.

7. The composite substrate of claim 3, wherein the nano-scale graphene film has a thickness of greater than 10 nanometers.

8. The composite substrate of claim 1, wherein the dielectric substrate consists of sapphire.

9. The composite substrate of claim 1, wherein the composite substrate is a component of an insulated gate bipolar transistor (IGBT) switching device.

10. An insulated gate bipolar transistor (IGBT) switching device comprising:
a composite substrate comprising a dielectric substrate having at least a first surface formed of sapphire, and a nano-scale graphene film on the first surface of the dielectric substrate;
a conductor layer bonded to a second surface of the composite substrate;
an IGBT chip and a diode chip electrically connected to the conductor layer with bond wires, the IGBT chip having a gate terminal and an emitter terminal electrically connected to the conductor layer; and
a base plate bonded to the nano-scale graphene layer of the composite substrate.

11. The IGBT switching device of claim 10, further comprising a heat sink bonded to the base plate.

12. The IGBT switching device of claim 10, wherein the nano-scale graphene film has a thickness of less than one micrometer.

13. The IGBT switching device of claim 12, wherein the nano-scale graphene film has a thickness of 500 nanometers or less.

14. The IGBT switching device of claim 13, wherein the nano-scale graphene film has a thickness of 200 nanometers or less.

15. The IGBT switching device of claim 12, wherein the nano-scale graphene film has a thickness of greater than 10 nanometers.

16. The IGBT switching device of claim 10, wherein the IGBT switching device lacks a heat sink bonded to the base plate.

17. The IGBT switching device of claim 10, wherein the IGBT switching device is a component of a power converter.

18. The IGBT switching device of claim 17, wherein the power converter is installed in an aerospace, defense, or electric vehicle application.

19. A method of improving the thermal performance of an IGBT switching device that comprises a dielectric substrate and a nano-scale graphene film, the method comprising reducing a lattice mismatch between with a surface of the dielectric substrate and the nano-scale graphene film.

20. The method of claim 19, wherein the step of reducing comprises forming the surface of the dielectric substrate of sapphire.
